(19) United States
(12) Patent Application Publication
(10) Pub. No.: US 2008/0035470 A1
(43) Pub. Date: Feb. 14, 2008

(54) Device For Plasma-Treating And/Or Coating Work Pieces

(75) Inventors: Roel Tietema, Venlo (NL); Dave Doerwald, Nijmegen (NL); Roger J.H. Gubbels, Venlo (NL); Anthonie J.A. Kaland, Eindhoven (NL)

Correspondence Address: HARNESS, DICKEY & PIERCE, P.L.C., P.O. BOX 828, BLOOMFIELD HILLS, MI, 48303, US

(73) Assignee: HAUZER TECHNO-COATING B.V., Venlo (NL)

(21) Appl. No.: 11/661,561

(22) PCT Filed: Apr. 5, 2006
(86) PCT No.: PCT/EP06/03118

§ 371 Date: Feb. 28, 2007

(30) Foreign Application Priority Data
Apr. 12, 2005 (EP) 05007933.4

(51) Int. Cl. C23C 14/34

(52) U.S. Cl. 204/192.13; 204/298.03; 204/298.28

(57) ABSTRACT

The invention relates to a device for the plasma and/or coating treatment of workpieces comprising a chamber (2) that can be evacuated, a holding device (3) for the workpieces to be treated that is rotatably mounted within the chamber (2) and a plasma source (4). In order to create a device of the above mentioned type that enables the treatment of relatively great workpieces with respect to the size of the device, the invention proposes that the plasma source (4) is placed within the chamber (2), for which purpose the at least one cathode (5) and the least one anode (6) of the plasma source (4) are mounted on the upper side or lower side (7, 8) inside the chamber (2).

The invention relates to a device for the plasma and/or coating treatment of workpieces comprising a chamber that can be evacuated, a holding device for the workpieces to be treated that is rotatably mounted within the chamber and a plasma source.

Such a device is for example known from EP 0 413 853 B1. The here described device comprises a treatment chamber that can be evacuated and a workpiece holding device placed within the treatment chamber. The workpiece holding device is rotatable around the central axis of the treatment chamber and serves for receiving the workpieces to be treated. Outside the treatment chamber, a cathode chamber is placed on the upper side thereof, which cathode chamber cooperates with an anode provided on the lower side of the treatment chamber and thus enables the generation of a low-voltage arc discharge along the central axis of the treatment chamber. The cathode chamber is separated from the treatment chamber by means of isolators and is in communication with the treatment chamber via a screen that comprises a small opening. Furthermore, magnetron scattering sources are provided which are flanged from outside to the chamber wall of the treatment chamber.

For operating the low-voltage arc discharge, the cathode is heated by means of a heating current supply device, such that the cathode imitates electrodes. Another power supply for the operation of the arc discharge is provided between the cathode and the anode.

The workpiece holding device for receiving the workpieces to be treated is preferably rotationally symmetrical and placed between the arc discharge on the one hand and the chamber wall of the treatment chamber on the other hand, such that the workpieces received by the workpiece holding device can be rotated around the central axis of the treatment chamber. The cathode chamber preferably has a gas inlet, via which the cathode chamber can be supplied with a working gas, for example argon, so that the workpieces to be treated can be submitted both to an electron bombardment and to a ion bombardment by means of the low-voltage arc discharge. By applying a negative tension to the workpieces to be treated a ion bombardment will take place, whereas by applying a positive tension to the workpieces to be treated an electron bombardment of the workpieces will become possible. Thus, before the coating operation, the workpieces can be pre-treated by means of the plasma source, in case of an electron bombardment by cleaning and heating-up, on the one hand, and in case of a ion bombardment by scattering etching, on the other hand. After such a pre-treatment, the workpieces can be coated by scattering by means of the magnetron scattering sources.

It is a drawback of the above described device that it is not suitable for also treating big workpieces. Due to the electron beam of the plasma source that passes centrally through the treatment chamber, only the annular space that is formed between the electron beam and the chamber wall can be used as actual treatment space of the workpieces. Thus, the size of the workpieces that can be treated by the known device is limited to the dimensions defined by the annular space. Although the treatment chamber could principally also receive bigger workpieces, a treatment of these ones is not possible due the central orientation of the electron beam of the plasma source with respect to the treatment chamber.

In order to overcome the above mentioned drawback, EP 0 886 880 B1 proposes a device for coating workpieces, in which the cathode-anode arrangement that forms the plasma source is placed outside the treatment chamber on the side wall thereof. Due to this arrangement it is achieved that the volume space encompassed by the treatment chamber can nearly be completely used for the treatment of workpieces, such that in contrast to EP 0 413 853 B1 bigger workpieces can be treated in a treatment chamber of the same size. However, this advantage is purchased by the drawback that the device as such has greater geometrical dimensions, since according to EP 0 886 880 B1 the cathode-anode arrangement is flanged to the outer circumference of the treatment chamber. This does not only result in a bigger and thus more bulky device as such, but also precious space for the placement of the scattering sources is lost due to the outer location of the cathode chamber. Furthermore, it is a drawback that the cathode chamber has to be very cumbersome and of big volume due to the fact that the low-voltage arc discharge has to be spaced at least 10 cm from the workpieces to be treated. Thus, it might be possible to treat bigger workpieces with the device according to EP 0 886 880 B1 than with the device according to EP 0 413 853 B1, but this requires, in spite of a treatment chamber of the same size, a device that is altogether bigger.

It is the object of the invention to propose a device for the plasma and/or coating treatment of workpieces that enables the coating of relatively big workpieces in comparison to the size of the device, while avoiding the above mentioned drawbacks. The invention shall also propose a method for the plasma and/or coating treatment of workpieces.

This aim is achieved by a device for the plasma and/or coating treatment of workpieces comprising a chamber that can be evacuated, a holding device for the workpieces to be treated that is rotatably mounted within the chamber and a plasma source, characterized in that the plasma source is placed within the chamber, for which purpose the at least one cathode and the least one anode of the plasma source are mounted on the upper side or lower side inside the chamber.

The device according to the invention is characterized in that the cathode-anode arrangement that forms the plasma source is placed inside the treatment chamber. In contrast to what is known from the state of the art, no cathode chamber having a big volume is formed outside the treatment space, such that the device as such has an altogether compact construction. Furthermore, it is an advantage that the complete circumferential area of the treatment chamber can be used for placing coating sources. The mounting of such coating sources is not impeded by cathode-anode arrangements outside the treatment chamber, as it is the case in the state of the art.

The at least one cathode and the least one anode of the plasma source are provided on the upper respectively lower side of the interior of the chamber. The cathode and anode are thus facing each other, wherein the cathode is preferably placed on the ceiling and the anode is preferably placed on the bottom of the treatment chamber. In order to obtain an effectively usable treatment space that is as big as possible within the treatment chamber, the cathode and the anode have to be located eccentrically, i.e. on the side wall of the treatment space. With such an arrangement of cathode and anode, the plasma source is formed between the holding device of the workpieces to be treated on the one hand and the chamber side wall on the other hand, wherein the plasma source acts radially inwards upon the workpieces carried by the holding device. Such a design permits to achieve a relatively big useful space inside the treatment chamber with respect to the size of the device, which space also allows the treatment of big workpieces.

According to another aspect of the invention it is provided that the cathode and the anode are mounted inside the chamber such that the electron beam generated between cathode and anode extends in parallel to the rotation axis of the holding device. Hereby an especially space-saving arrangement is achieved, such that the space provided by the treatment chamber can be used in an optimum way. The space-saving arrangement is further improved by the fact that the cathode-anode arrangement is placed as closely as possible to the chamber side wall, wherein the distance between holding device and electron beam is smaller that the distance between chamber wall and electron beam. Herein, the distance between holding device and electron beam is less than 20 cm, preferably less than 10 cm, more preferably less than 7 cm. This close distance enables a high plasma density on the substrates, i.e. the workpieces to be treated.

In view of the treatment result that one wishes to obtain the parallel orientation of the electron beam is not imperative, but other arrangements of cathode and anode are also possible. According to an alternative realisation mode of the invention, the cathode and the anode can be placed inside the chamber such that the electron beam that forms between cathode and anode extends transversely to the rotation axis of the holding device. Such a formation of the electron beam can be for example achieved in that cathode and anode are spaced from each other in horizontal direction. The electron beam that forms between cathode and anode thus extends diagonally through the treatment space provided by the treatment chamber, i.e. transversely to the rotation axis of the holding device.

According to another aspect of the invention, the distance between anode and holding device is comprised between 0.5 cm and 3.5 cm, preferably between 1.5 cm and 2.5 cm. The distance between cathode and holding device can vary between 1.0 cm and 7.5 cm, preferably between 1.5 cm and 5.5 cm.

The holding device that can be a supporting structure, table or the like, is preferably mounted centrally inside the treatment chamber, such that the distance between holding device on the one hand and provided sources on the other hand is respectively the same. For changing the distance, preferably the positions of the respective sources can be optionally variable, i.e. adjustable. The workpieces to be treated can be received by the holding device in a vertical or horizontal orientation. A vertical orientation is preferred, according to which the workpieces are oriented in parallel to the direction into which the plasma source extends, but it can also be provided to arrange the cathode-anode arrangement that forms the plasma source in such a way that the plasma source extends essentially along the workpieces to be treated also in case of a horizontal orientation of these ones. Furthermore, the cathode-anode arrangement can be placed such that the plasma beam is directed transversely in a sort of diagonal direction through the substrate holding device (holding device).

Since according to the invention the cathode-anode arrangement is placed relatively close to the holding device and thus to the workpieces carried by the holding device, there is the danger of an undesired arc ignition on the workpieces to be treated. In order to exclude this and to protect the workpieces against an unintended arc ignition, it is provided that the cathode and the anode are connected to a common source of current, wherein a current breaker is provided for breaking the cathode-anode circuit. The current breaker can be placed between the cathode on the one hand and the source of current on the other hand or between the anode on the one hand and the source of current on the other hand. The current breaker is preferably provided in form of a high speed circuit breaker. The current breaker takes care that the plasma source current is directly cut off as soon as an undesired arc discharge is generated on the workpieces to be treated. For preventing the plasma source current from being interrupted for too long, the plasma source is ignited by a high-voltage discharge, if necessary supported by a short-term pressure increase inside the treatment chamber.

According to another aspect of the invention, the holding device is connected to a current supply, wherein the negative pole of the current supply is adjacent to the holding device and wherein a tension and/or current meter is placed between the holding device and the current supply. It is the purpose of the tension and/or current meter to detect tension and/or current variations in the holding device that are generated on the workpieces to be treated due to undesired arc discharges. The tension and/or current meter is in communication with the current breaker of the cathode-anode circuit such that this one can be switched depending on the signal detected by the tension and/or current meter. For this purpose, an electronic control module is provided which measures certain tension and/or current variations in the holding device by means of the tension and/or current meter and sends a signal corresponding to the measurement to the current breaker of the cathode-anode circuit for breaking the cathode-anode circuit. In this way it is assured that the plasma source current is automatically interrupted as soon as an undesired arc ignition takes place on the workpieces to be treated. In order to prevent a new ignition of an arc, fed by the plasma current supply, an as short response time of the electronic control module as possible has to be provided. Therefore, the electronic control module preferably has a response time comprised between 20 μsec and 250 msec, preferably between 10 msec and 100 msec. The cutoff period of the bias tension should be sufficiently long such that a new ignition of the arc on the substrates (workpieces) can be avoided. This means that the cutoff period should be comprised between 10 msec and 100 msec, wherein the cutoff period should be preferably chosen as short as possible, in order to not prolong the process time unnecessarily.

The plasma source used according to the invention, that can be called an electron beam evaporator, preferably is a hot or cold cathode source.

According to another proposal of the invention, the device has at least one evaporator source that is placed on the chamber wall. Since the cathode-anode arrangement that forms the plasma source is located inside the treatment chamber, the at least one evaporator source can be placed at any point of the circumference both inside and outside the treatment chamber. The device preferably comprises a plurality of evaporator sources which can be equally spaced from each other on the side wall of the treatment chamber. Herein, the distance between evaporator source and holding device is essentially the same as the distance between holding device and chamber wall.

With respect to the method, the above mentioned aim is achieved by a method for the plasma and/or coating treatment of workpieces in a chamber that can be evacuated comprising a holding device for the workpieces to be treated that is rotatably mounted within the chamber that can be evacuated, characterized in that a cathode-anode arrangement that is placed inside the chamber and that forms a plasma source generates an electron beam between cathode and anode, wherein the cathode-anode circuit is broken as soon as a certain tension and/or current variation between the holding device connected to the negative pole of a current supply and the current supply is detected.

According to this method according to the invention it is provided that the plasma source circuit is directly broken as soon as a certain tension and/or current variation is generated between the holding device of the workpieces to be treated that is connected to the negative pole of a current supply and the current supply, caused by an undesired arc ignition on the workpieces to be treated. Thanks to this procedure, the workpieces to be treated are protected against eventual damages caused by undesired arc ignitions that would otherwise be fed by the plasma source.

In order to prevent the plasma source current from being cut off for too long, it is proposed according to another aspect of the invention that the plasma source is ignited by means of a high-voltage discharge, for example in form of a spark, while the chamber pressure is increased for a short time, if necessary. Hereby, plasma is generated in the electron path between cathode and anode, due to which the electron beam is formed on this path.

During the ignition of the plasma source, the current supply connected to the holding device is interrupted for not impairing the ignition of the plasma source by the negative pole that is adjacent to the holding device.

According to another aspect of the invention, for the plasma and coating treatment a plasma treatment of the workpieces by charged particle bombardment is carried out in a first step and a coating of the workpieces by means of at least one evaporator source located on the chamber wall is carried out in a second step, wherein ions, preferably argon ions, are used as charged particles. Herein, the step of the plasma treatment serves for cleaning and heating the workpieces to be treated, whereas a coating of the workpieces is provided by the second step, which can be carried out by means of for example magnetron coating sources and/or arc sources. As coating sources, principally scattering sources or arc sources can be used. PA-CVD (plasma supported method) can also be used, in which it is directly worked from the gas phase without material evaporation of the cathodes.

Other characteristics and advantages of the invention will appear from the description that refers to the annexed figures. Herein:

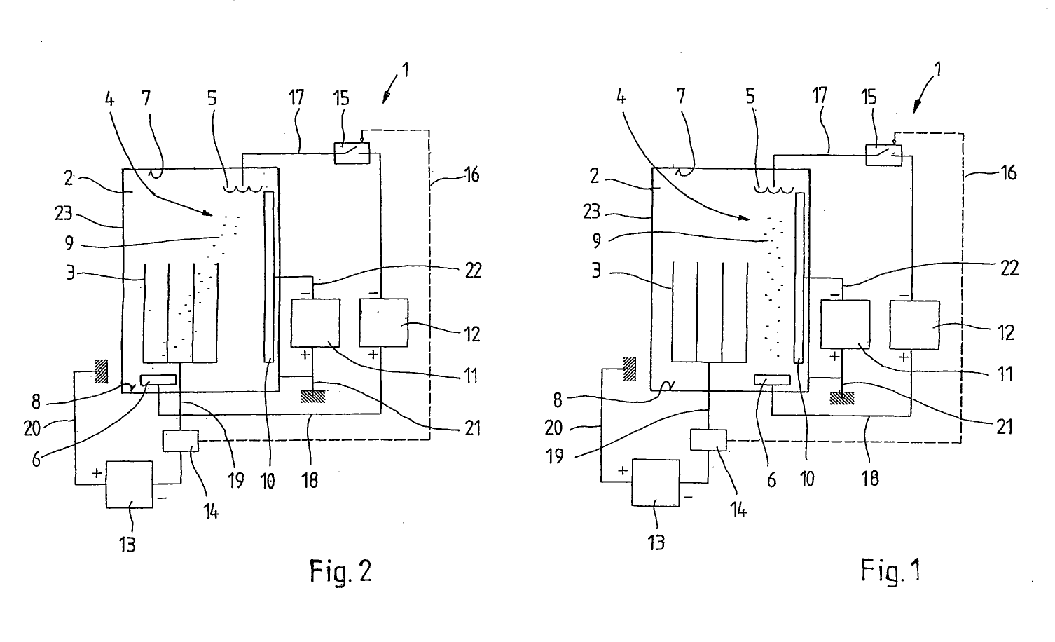

FIG. 1 is a schematic representation of a first realisation mode of the invention and

FIG. 2 is a schematic representation of a second realisation mode of the invention.

FIGS. 1 and 2 are schematic representations of a first and second realisation mode of the invention. The same reference numerals that are indicated in the figures identify the same elements.

The device 1 according to the invention is represented in FIGS. 1 and 2. This device comprises a treatment chamber 2, within which a holding device 3 serves for receiving the workpieces to be treated that are not represented in the figures. The holding device 3 preferably has the form of a stand and is arranged rotatably inside the treatment chamber 2.

Furthermore, a plasma source 4 is located inside the treatment chamber 2. The plasma source 4 is formed by a cathode 5 placed inside the chamber on the one hand and an anode 6 on the other hand. The electron beam 9 that is formed between cathode 5 and anode 6 in case of an intended use of the device 1 extends in parallel to the rotation axis of the holding device 3 according to the exemplary embodiment of FIG. 1. According to the exemplary embodiment of FIG. 2, cathode 5 and anode 6 are placed such that the electron beam formed between cathode 5 and anode 6 extends transversely to the rotation axis of the holding device 3. Herein, both realisation modes have in common that the cathode 5 is placed on the upper side 7 of the chamber and the anode 6 is placed on the lower side 8 of the chamber.

Referring to the exemplary embodiment according to FIG. 1 it is visible that the electron beam 9 formed between cathode 5 and anode 6 is arranged between holding device 3 on the one hand and lateral chamber wall 23 on the other hand. In order to create an as great useful space inside the treatment chamber 2 as possible, the distance between holding device 3 and electron beam 9 is smaller than the distance between chamber wall 23 and electron beam 9. The distance between holding device 3 and electron beam 9 is preferably less than 20 cm, preferably less than 10 cm.

As it can be furthermore seen in FIGS. 1 and 2, an evaporator source 10 is furthermore placed inside the treatment chamber 2, which evaporator source is positioned in the lateral chamber wall 23. Herein, the distance between evaporator source 10 and holding device 3 is essentially the same as the distance between holding device 3 and chamber wall 23.

The cathode-anode arrangement that forms the plasma source 4 is fed by means of a source of current 12. Herein, the negative pole 17 of the source of current 12 is adjacent to the cathode 5 and the positive pole 18 of the source of current 12 is adjacent to the anode 6. The plasma source 4 that is a hot or cold cathode source is preferably operated by means of direct-current, for which reason the source of current 12 is a source of direct-current.

The evaporator source 10 is fed by means of a source of current 11, wherein the negative pole 22 of the source of current 11 is adjacent to the evaporator source 10 and the positive pole 21 of the source of current 11 is adjacent to the treatment chamber 2.

Furthermore, a current supply 13 is provided, wherein the negative pole 19 of the current supply 13 is adjacent to the holding device. The positive pole 20 of the current supply 13 is connected to the treatment chamber 2.

Between cathode 5 on the one hand and source of current 12 on the other hand, a current breaker 15 is provided which preferably has the form of a quickly switchable circuit breaker, wherein source of current 12 and current breaker 15 can be formed integrally. The current breaker 15 is in communication with a tension and/or current meter 14 that is placed between holding device 3 and current supply 13 and is preferably integrated in the bias supply. An electronic control module that is not shown in the figures is also provided, which measures tension and/or current variations in the holding device 3 by means of the tension and/or current meter 14 and sends a signal 16 corresponding to the measurement to the current breaker 15 of the cathode-anode circuit for breaking this one.

The plasma source 4 is formed by means of the electron beam 9 which extends between cathode 5 and anode 6 when the source of current 12 is switched on. As shown in FIG. 1, the position of cathode 5 and anode 6 can be chosen such that the electron beam 9 extends laterally of the holding device 3, wherein the cathode 5 is placed on the upper side, i.e. on the ceiling of the treatment chamber 2, and the anode 6 is placed on the lower side, i.e. on the bottom of the treatment chamber 2. Another orientation of the electron beam 9 is also possible, as exemplarily shown in FIG. 2, according to which the cathode 5 and the anode 6 are arranged such that the electron beam 9 that is formed between them extends diagonally through the treatment chamber 2, i.e. transversely to the rotation axis of the holding device 3. Independent from the positioning of the cathode 5 or the anode 6, the electron beam 19 can for example be conical when an annular anode is used. It is also possible to obtain an electron beam 19 that is wider in the centre than in the end areas thereof.

Preferably the distance between holding device 3 and electron beam 9 is considerably less than 20 cm, preferably less than 10 cm and more preferably less than 7 cm. The electron beam 9 generates gas ions, preferably argon gas ions for the case that the plasma source is used for etching, in order to assure the required physical property of quasi neutrality in the plasma. During etching the etching effect can be influenced by the electron beam 9 of the plasma source by means of adjustment of the plasma source current supply on the one hand and by the voltage applied to the holding device 3 on the other hand. The electron current density determines the argon gas density, whereas the voltage applied to the holding device 3 determines with how much energy argon gas ions from the plasma column strike on the workpieces carried by the holding device 3. As plasma source current supply a DC supply is used, wherein the positive pole 18 is connected to the anode 6 and the negative pole 17 is connected to the cathode 5. It is also possible to use a plasma source fed with pulsed direct-current or with alternating current, wherein in this case anode 6 and cathode 5 are alternately triggered.

In the case of a current supply by means of direct-current, the cathode 5 preferably consists of a hot cathode source which has a resistance wire for generating an electron emission. After heating up the resistance or heating wire, a low-voltage arc discharge is ignited between the heating wire serving as cathode 5 and the anode 6 of the plasma source by means of the direct-current source. For ignition an auxiliary circuit may be used which releases an auxiliary discharge that ignites supplementary plasma in the direct proximity of the path of the electron beam 9 between cathode 5 and anode 6.

Both the cathode 5 and the anode 6 are isolated and suspended opposite the earth potential. For making the electron beam controllable, i.e. for preventing it from extending in parasitic paths which are more spaced from the workpieces to be treated, for example for avoiding local discharge concentrations, which can lead to non uniform plasma etchings on the workpieces to be treated, the cathode 5 and the anode 6 are surrounded by screens and/or insulations which are not represented in detail in the figures.

Usually the heating or resistance wire of the cathode 5 is situated in the ceiling of the treatment chamber 2 on the upper side thereof. The anode 6 is usually situated opposite the cathode 5 on the lower side of the treatment chamber 2. When the source of current 12 is switched on, an electron beam 9 is formed between anode 6 and cathode 5, wherein the energy of the electrons is used to convert the argon atoms supplied by a gas inlet that is not represented in the figures into argon ions. The electron beam 9 thus forms an argon ion source and is the true plasma source 4.

Plasma source 4 and evaporator source 10 are radially arranged and equally acting, which means in the sense of the invention that the effect of the plasma source 4 as well as the effect of the evaporator source 10 acts in the direction of the holding device 3 and the workpieces carried by it.

For protecting the workpieces it is necessary to cut off the plasma source current supply at once if an undesired arc discharge is generated on the workpieces, in order to avoid the risk that an arc ignited on the workpieces and fed by the energy of the direct-voltage supply of the plasma source 4 continues. For this purpose, the current supply of the plasma source has a current breaker 15, as described above.

For preventing the plasma source current from being cut off for too long, the plasma source is ignited via a high-voltage discharge, if necessary, supported by a short-term pressure increase inside the treatment chamber 2. During ignition the voltage applied to the holding device 3 is broken so that the negative switching of the holding device 3 is not impeding the ignition procedure.

In order to be able to assure a stable operation of the plasma source 4, it is necessary that the electron beam 9 is separated, i.e. isolated, from the chamber wall 23 by means of suitable measures. Suitable measures in this context can be the installation of (electric) screens between electron beam 9 and chamber wall 23 as well as between anode 6 and chamber wall 23 as well as between anode 6 and lower side of the holding device 3.

If the plasma source 4 is active and if a voltage is simultaneously applied to the holding device 3 it is possible that due to the close juxtaposition of plasma source 4, i.e. electron beam 9 and holding device 3, i.e. the workpieces carried by the holding device 3 an undesired arc is ignited on the workpieces, which can lead to damages of the workpieces. In order to be able to efficiently exclude such damages, the device according to the invention comprises an arc recognition unit in form of a tension and/or current meter 14, which is placed in the circuit between holding device 3 and current supply 13.

The tension and/or current meter 14 detects certain voltage and/or current variations caused by undesired arc ignitions on the workpieces and sends a signal 16 corresponding to the measurement via a corresponding electronic control module to the current breaker 15 of the plasma source current supply, such that in case of an undesired arc discharge this one will be recognized and the plasma source current supply can be cut off as soon as possible. The arc recognition of the arc recognition unit, i.e. of the tension and/or current meter 14, should be as quick as possible in order to prevent a new ignition of an arc fed by the plasma source current supply. The waiting time should preferably be comprised between 100 μsec and 200 μsec, preferably less than 150 μsec, wherein the setting of the waiting time until the bias voltage is applied again, has to be chosen such that it is long enough for preventing an undesired new ignition. As long as the waiting time is lasting, the plasma source is electronically cut off, as described above, wherein the plasma source is switched of about 50 μsec after detection of the arc. If an arc is recognized on the substrate holding device, the bias voltage will also be cut off as soon as possible. Simultaneously with switching of the bias voltage—eventually also some time later—the plasma source current will be cut off in order to prevent a new ignition of the arc on the substrate (workpiece).

### LIST OF REFERENCE NUMERALS

1 device

2 chamber

3 holding device

4 plasma source

5 cathode

6 anode

7 upper side of the chamber

8 lower side of the chamber

9 electron beam

10 evaporator source

11 source of current

12 source of current

13 current supply

14 tension or current meter

15 current breaker

16 signal

17 negative pole

18 positive pole

19 negative pole

20 positive pole

21 positive pole

22 negative pole

23 chamber wall

1. A device for the plasma and/or coating treatment of workpieces comprising a chamber that can be evacuated, a holding device for the workpieces to be treated that is rotatably mounted within the chamber and a plasma source,
wherein
the plasma source is placed within the chamber, for which purpose the at least one cathode and the least one anode of the plasma source are mounted on the upper side or lower side inside the chamber.

2. A device according to claim 1, wherein the cathode and the anode are mounted inside the chamber such that the electron beam generated between cathode and anode extends in parallel to the rotation axis of the holding device.

3. A device according to claim 2, wherein the distance between holding device and electron beam is smaller than the distance between chamber wall and electron beam.

4. A device according to claim 3, wherein the distance between holding device and electron beam is smaller than 20 cm, preferably smaller than 10 cm.

5. A device according to claim 1, wherein the cathode and the anode can be placed inside the chamber such that the electron beam that is formed between cathode and anode extends transversely to the rotation axis of the holding device.

6. A device according to claim 1, wherein the distance between anode and holding device is comprised between 0.5 cm and 3.5 cm, preferably between 1.5 cm and 2.5 cm.

7. A device according to claim 1, wherein the distance between cathode and holding device is comprised between 1.0 cm and 7.5 cm, preferably between 1.5 cm and 5.5 cm.

8. A device according to claim 1, wherein the cathode and the anode are connected to a common source of current, wherein a current breaker, preferably in the form of a high-speed circuit breaker, is provided between said cathode on the one hand and said source of current on the other hand.

9. A device according to claim 1, wherein the source of current is a direct-current source.

10. A device according to claim 1, wherein the holding device is connected to a current supply, wherein the negative pole of the current supply is adjacent to the holding device and wherein a tension and/or current meter is placed between said holding device and said current supply.

11. A device according to claim 1, wherein the tension and/or current meter is in communication with the current breaker of the cathode-anode circuit.

12. A device according to claim 1, comprising an electronic control module which measures tension and/or current variations in the holding device by means of the tension and/or current meter and sends a signal corresponding to the measurement to the current breaker of the cathode-anode circuit for breaking the cathode-anode circuit.

13. A device according to claim 12, wherein the electronic control module has a response time of less than 50 μsec, preferably of less than 20 μsec.

14. A device according to claim 1, wherein the plasma source is a hot or cold cathode source.

15. A device according to claim 1, comprising at least one evaporator source located on the chamber wall.

16. A device according to claim 1, wherein the distance between evaporator source and holding device is essentially the same as the distance between holding device and chamber wall.

17. A method for the plasma and/or coating treatment of workpieces in a chamber that can be evacuated comprising a holding device for the workpieces to be treated that is rotatably mounted within the chamber that can be evacuated, wherein a cathode-anode arrangement that is placed inside said chamber and that forms a plasma source generates an electron beam between cathode and anode, wherein the cathode-anode circuit is broken as soon as a tension and/or current potential between the holding device connected to the negative pole of a current supply and the current supply is detected.

18. A method according to claim 17, wherein the plasma source is ignited by means of a high-voltage discharge.

19. A method according to claim 17, wherein the plasma source is ignited while increasing the pressure of the chamber for a short time.

20. A method according to claim 17, wherein the current supply connected to the holding device is broken during the ignition of the plasma source.

21. A method according to claim 17, wherein a plasma treatment of the workpieces by charged particle bombardment is carried out in a first step and a coating of the workpieces by means of at least one evaporator source located on the chamber wall is carried out in a second step, wherein ions, preferably argon ions, are used as charged particles.
